(19) United States
(12) Patent Application Publication
(10) Pub. No.: US 2004/0079289 A1
(43) Pub. Date: Apr. 29, 2004

(54) Electrostatic chuck wafer port and top plate with edge shielding and gas scavenging

(76) Inventors: Peter L. Kellerman, Essex, MA (US); Kevin T. Ryan, Wilmington, MA (US); Robert J. Mitchell, Winchester, MA (US)

Correspondence Address: DINSMORE & SHOHL LLP, ONE DAYTON CENTRE, SUITE 500, ONE SOUTH MAIN STREET, DAYTON, OH, 45402-2023, US

(21) Appl. No.: 10/278,640

(22) Filed: Oct. 23, 2002

(51) Int. Cl. C23C 16/00

(52) U.S. Cl. 118/728

(57) ABSTRACT

An apparatus for processing a semiconductor wafer. The apparatus according to the present invention comprises a wafer port flange including an electrostatic chuck and a top plate including a lip. The electrostatic chuck defines a circumferential gas distribution groove and a gas gap positioned between a backside of a semiconductor wafer and the electrostatic chuck. The lip is positioned to shield an outside band of the wafer. It is emphasized that this abstract is provided to comply with the rules requiring an abstract that will allow a searcher or other reader to quickly ascertain the subject matter of the technical disclosure. It is submitted with the understanding that it will not be used to interpret or limit the scope or meaning of the claims. 37 CFR §1.72(b).

### BACKGROUND OF THE INVENTION

The present invention relates in general to apparatus used in fabricating semiconductor wafers and, more particularly, to an electrostatic chuck wafer port and top plate that provides edge shielding of a wafer from an energy source and gas scavenging of a source of cooling gas used to maintain an even wafer temperature.

Generally, in high-vacuum systems for treating a semiconductor wafer, an energy source heats the wafer. For example, in an ion implanter, a high-energy ion beam transports energy (along with ions) to the wafer, which raises the temperature of the wafer as the energy from the beam is converted into heat. In order to control the temperature of the wafer, backside cooling gas is often introduced in a pressure distribution groove positioned on an electrostatic chuck, which is adjacent to the wafer. The electrostatic chuck holds the wafer during processing. The cooling gas fills a narrow space between the wafer and the chuck and provides a thermal conduction conduit, which carries heat away from the wafer to a water cooled base.

The pressure distribution groove is commonly located close to the edge of the electrostatic chuck, so that outward gas flow is confined to a gas flow region near the edge. The remaining portion of the conduit between the wafer and the chuck contains cooling gas that is at a uniform pressure P (typically between about 10 and about 200 Torr), and therefore, provides constant heat conductivity to the cooling plate. In contrast, the pressure of the cooling gas within the gas flow region varies from P to the high vacuum pressure (<<1 Torr), so that the conductivity of the cooling plate is reduced, which leads to edge heating of the wafer. Given that the conductivity of the Si-based semiconductor is higher than that of the cooling gas, a hot spot will extend from the heated edge of the wafer toward the center. Although this higher edge temperature is not significant for most processes, where it is only required that the photoresist remain intact, it is critical for processes that require precise temperature control, such as oxygen implantation for SIMOX. In this case, the temperature non-uniformity caused by the reduced edge cooling can lead to semiconductor wafers with unreliable specifications.

Also in these high-vacuum systems, a gas scavenging groove is commonly employed at the edge of the electrostatic chuck to avoid contaminating the processing chamber with cooling gas. However, by placing the pressure distribution groove close to the edge of the chuck, significant design limitations are imposed on the placement of a gas scavenging groove adjacent to the pressure distribution groove. Moreover, a preferred method of wafer handling has become edge griping, since it introduces the least amount of particle contamination on either side of the wafer. In order to achieve this, approximately 1 mm of edge needs to be accessible from both sides of the wafer, further exacerbating the edge cooling problem. Finally, the prior art fails to provide mechanical means for preventing a wafer from falling into the chamber should the electrostatic chuck fail during processing of a wafer in an upside down orientation.

Accordingly, the present inventors have recognized a need for improvements in electrostatic chuck wafer port design.

### SUMMARY OF THE INVENTION

The present invention meets the above-specified needs by providing an apparatus for processing a semiconductor wafer in a high-vacuum chamber, in which the wafer is exposed to a uniform (on average) energy source. The apparatus comprises a wafer port flange including an electrostatic chuck, and a top plate including a lip that shields an outside band of the wafer.

Although the present invention is not limited to specific advantages or functionality, it is noted that the lip in the top plate, by providing edge shielding of the wafer from the energy source, effectively removes the heat source from the uncooled edge, thus resulting in a uniform temperature across the wafer. It is further noted that the lip serves to restrict the flow of a source of cooling gas into the high-vacuum chamber. It is still further noted that because the shielded band portion of the wafer need not be cooled, the lip enables the wafer to overhang the electrostatic clamp, thereby allowing edge clamping for wafer handling purposes. It is still yet further noted that in applications where the wafer is processed upside down, the lip serves as a “safety net”, thus mechanically preventing the wafer from falling into the high-vacuum chamber if the electrostatic chuck fails.

In accordance with one embodiment of the present invention, an apparatus for processing a semiconductor wafer is provided comprising a wafer port flange and a top plate. The wafer port flange includes an electrostatic chuck that defines a circumferential gas distribution groove and a gas gap positioned between a backside of a semiconductor wafer and the electrostatic chuck. The top plate includes a lip that is positioned to shield an outside band of the wafer.

These and other features and advantages of the present invention will be more fully understood from the following description of the invention taken together with the accompanying drawings. It is noted that the scope of the claims is defined by the recitations therein and not by the specific discussion of features and advantages set forth in the present description.

### BRIEF DESCRIPTION OF THE DRAWINGS

The following detailed description of the present invention can be best understood when read in conjunction with the following drawings, where like structure is indicated with like reference numerals and in which:

FIG. 1 is a schematic cross-sectional view of a wafer port flange and top plate for an apparatus for processing a semiconductor wafer according to the present invention;

FIG. 2 is a schematic block diagram illustrating one application for an apparatus for processing a semiconductor wafer according to the present invention; and

FIG. 3 is a graph showing temperature (° C.) vs. radial position (m) for a 300 mm wafer that has been uniformly heated over a front side area while being uniformly cooled over a reduced area on the backside.

Skilled artisans appreciate that elements in the figures are illustrated for simplicity and clarity and have not necessarily been drawn to scale. For example, the dimensions of some of the elements in the figures may be exaggerated relative to other elements to help improve understanding of the present invention.

### DETAILED DESCRIPTION OF THE INVENTION

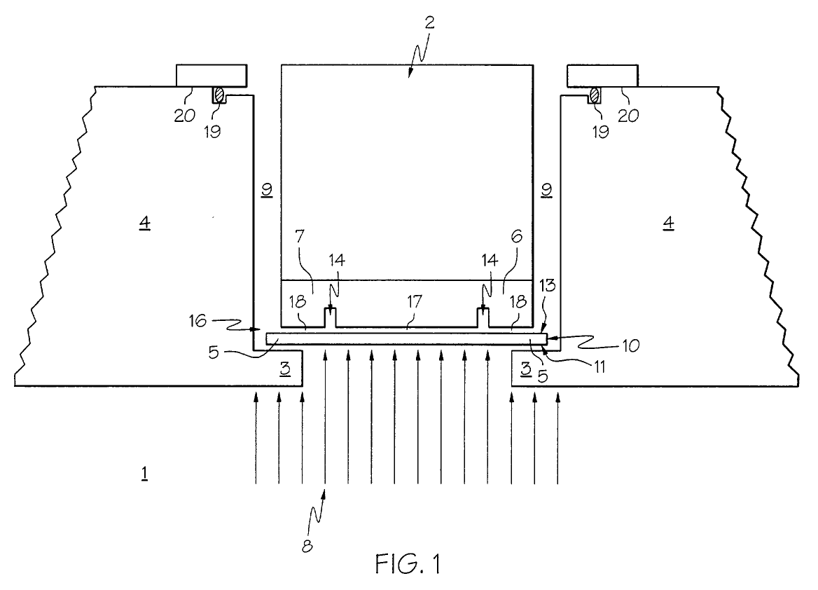

Referring initially to FIG. 1, an apparatus for processing a semiconductor wafer in accordance with one exemplary embodiment of the present invention, is illustrated. The apparatus comprises a wafer port flange 2 and top plate 4, which can both be positioned within a high-vacuum chamber, shown generally as numeric indicator 1. The high-vacuum chamber 1 provides a controlled environment for processing semiconductor wafers and can have an internal pressure of less than 1 Torr.

The wafer port flange 2 includes an electrostatic chuck 6 that is employed to hold a semiconductor wafer 10 within the high-vacuum chamber 1 for processing. While not shown, the electrostatic chuck 6 can further include a temperature controlled base member, an insulator layer, a dielectric layer, and a pair of electrodes, such as the electrostatic chuck described in commonly assigned U.S. Pat. No. 5,436,790 to Blake et al., which is hereby incorporated by reference for its description of a typical electrostatic chuck.

The semiconductor wafer 10 has a front side 11 and a backside 13. In addition, an energy source (not shown) is provided and is configured to focus a high-energy beam 8 onto the front side 11 of the semiconductor wafer 10. The energy beam 8 can be focused onto the front side 11 of the wafer 10 in a uniform manner across the diameter of the wafer 10, and can be selected from an ion beam, an electron beam, a gas plasma, and combinations thereof.

Although the present invention is configured to provide thermal conductivity for controlling the temperature of an article in a vacuum environment for a variety of potential applications, it is particularly applicable to providing edge shielding of a semiconductor wafer and scavenging of gasses employed for cooling a semiconductor wafer in an ion implantation system. Accordingly, the invention is described herein with respect to such an ion implantation system, for example, a SIMOX ion shower.

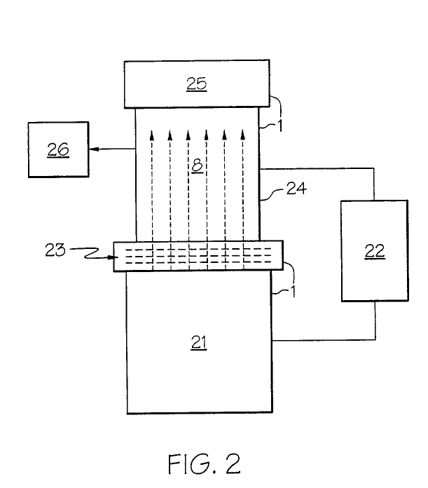

Referring now to FIG. 2, there is schematically illustrated a typical ion implantation system for use with the present invention, where ions from a uniform energy source 21 are generated for projection through a vertical accelerator column 23, along a beam line 24, to an end station 25. Here, the ions are directed onto a semiconductor wafer. The uniform energy source 21 is connected to a high-voltage power supply 22 and the uniform energy source 21, the accelerator column 23, the beam line 24, and the end station 25 are all contained within the high-vacuum chamber 1. The chamber 1 is maintained under high vacuum by a vacuum pumping device 26. Typically, the ion implantation system is operated at a pressure level that is less than or about 1×10⁻⁵ Torr when the ion beam is directed onto the wafer.

With reference again to FIG. 1, the wafer 10 is positioned against the electrostatic chuck 6 with the backside 13 of the wafer 10 facing the chuck 6. The electrostatic chuck 6 contains a circumferential gas distribution groove 14 and a gas gap 16 positioned between the backside 13 of the wafer 10 and the chuck 6. The circumferential gas distribution groove 14 can be positioned about 1 mm from an outer peripheral edge 7 of the electrostatic chuck 6. The groove 14 can be greater than or about 0.1 mm wide and less than or about 0.2 mm deep. The gas gap 16 can be less than or about 1 μm thick.

Upon coming in contact with the semiconductor wafer 10, the high-energy beam 8 is converted into heat energy, which raises the temperature of the wafer 10. In order to control the temperature of the semiconductor wafer 10, a source of cooling gas is introduced into the circumferential gas distribution groove 14, which flows into and fills the gas gap 16 to provide thermal conductivity for transferring heat from the wafer 10 to the electrostatic chuck 6 as described in commonly assigned U.S. Pat. Nos. 4,514,636 and 4,261,762, which are hereby incorporated by reference for their teaching of gas conduction cooling. The wafer port flange 2 that is adjacent to the electrostatic chuck 6 can be cooled by circulating a fluid such as water or freon through internal passages (not shown) fashioned within the wafer port flange 2. The source of cooling gas can be under pressure of greater than or about 1 Torr, and can comprise gas with a high thermal conductivity, such as, for example, nitrogen, neon, helium, or hydrogen. The source of cooling gas can be directed from a distant source through a regulator and leak valve (not shown) to the circumferential gas distribution groove 14.

The gas gap 16 further defines a uniform heat conduction area 17, which is bounded by the circumferential gas distribution groove 14. Cooling gas is initially fed from the source of cooling gas through the groove 14 until the gas pressure within the uniform heat conduction area 17 reaches equilibrium. Once this steady state is established, cooling gas flow occurs only in the area between the circumferential gas distribution groove 14 and the outer peripheral edge 7 of the electrostatic chuck 6 (the outer 1 mm of the wafer 10). There is no flow of cooling gas within the uniform heat conduction area 17 after the initial transient condition of establishing equilibrium pressure. Consequently, the gas pressure remains uniform across the majority of the semiconductor wafer 10 that is adjacent the uniform heat conduction area 17 and, therefore, provides constant heat conductivity. (Note that for the pressures and gaps considered here, the heat conduction is in the molecular free regime, and so the heat conduction is proportioned only to the pressure). However, there is a flow of gas between the groove 14 and the wafer edge, leading to a gradient in the pressure, which drops to the chamber 1 pressure (<<1 Torr) at the wafer edge. This means that the conduction to the cooled electrostatic chuck 6 drops to a very low value near the wafer edge. If a wafer is being uniformly heated by a uniform energy source, such as an ion beam, an imbalance of heating and cooling at the wafer edge amounts to edge heating. Since the conductivity of the semiconductor wafer is higher than the gas gap conductance, a hot spot will extend toward the center of the wafer. Although there is an edge exclusion of 3 mm on semiconductor wafers, the temperature affects of this 1 mm reduced thermal conductance area can extend well beyond this exclusion.

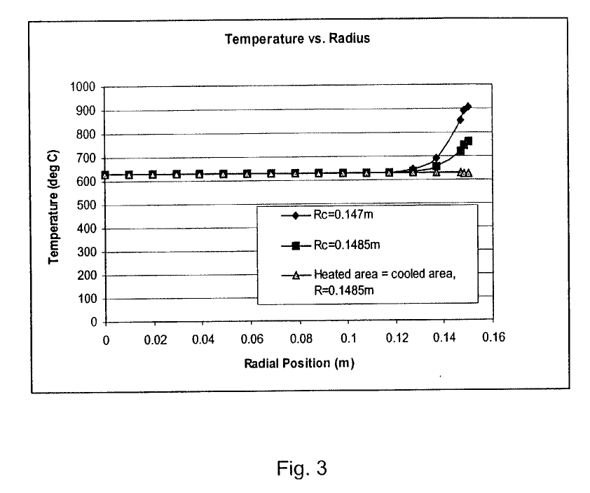

The magnitude of this problem can be determined using a finite element model for a 300 mm wafer that is being uniformly heated over the front side area while being uniformly cooled over a reduced area on the backside. With reference to FIG. 3, three plots are shown which illustrate 1) a cooled area defined by a radius of R_{c}=147 mm, 2) a cooled area defined by a radius of R_{c}=148.5 mm, and 3) a wafer where the heating is restricted to the 148.5 mm radius by a guard ring. The model parameters are typical for a SIMOX ion shower application:

Q=1.2ₑ6 W/m²;

hᵢ₌2000 W/m²° C.;

hₒ=0; and

K=120 W/m° C.

where Q is the energy flux imparted by the energy beam, hᵢ is the heat transfer coefficient in the inner gas cooled area of the wafer, hₒ is the heat transfer coefficient in the outer shielded area, and K is the conductivity of Si. The results indicate the effect that the small non-cooled edge area has on temperature uniformity across the wafer. If the heated area is made equal to the cooled area, the temperature will essentially be uniform across the wafer.

In accordance with these results, the top plate 4 of the present invention includes a lip 3 that is positioned to shield an outside band 5 of the semiconductor wafer 10 from the high-energy beam 8, while still allowing the beam 8 to contact the cooled portion of the wafer 10 adjacent the uniform heat conduction area 17. The outside band 5 comprises less than or about 3 mm of the semiconductor wafer 10. By providing edge shielding of the outside band 5 of the wafer 10 from the high-energy beam 8, which is adjacent the reduced thermal conductance area 18, the lip 3 is effective in removing the heat source from the uncooled edge of the wafer 10. The lip 3 provides for a uniform temperature across the portion of the wafer 10 that is subjected to the high-energy beam 8. Thus, the present invention solves the problems associated with edge heating of semiconductor wafers when subjected to a uniform energy source.

The top plate 4 and, more particularly, the lip 3, can be fluid (water) cooled, so that it can withstand the constant bombardment of the high-energy beam 8. Moreover, the lip 3 and the top plate 4 can comprise a silicon coating so to not cause any contamination of the wafer 10. This silicon coating can be doped (typically with boron) in order to make it electrically conductive, preventing an ion beam from charging it to a high potential and causing arcing.

In accordance with the present invention, the top plate 4 is separated from the electrostatic chuck 6 by a gap that is greater than or about 1 mm. Accordingly, the lip 3 can be positioned less than or about 0.1 mm from the front side 11 of the wafer 10. By introducing the cooling gas into the circumferential gas distribution groove 14 of the electrostatic chuck 6, there will be a flow of gas through the gap between the electrostatic chuck 6 and the wafer 10 outward into a pumping channel 9. The pumping channel 9 is positioned between the wafer port flange 2 and the top plate 4. Since the conductance of the pumping channel 9 (>1 mm wide) is much greater than the conductance defined by the lip 3 and the front side 11 of the wafer 10 (<0.1 mm), most of this gas will flow out of the pumping channel 9, rather than into the high-vacuum chamber 1. This feature can reduce gas flow into the chamber 1 by at least a factor of 10.

The wafer 10 has a thickness tolerance of less than or about 0.025 mm. Thus, the small gap between the lip 3 and the front side 11 of the wafer 10 can be achieved repeatedly. Accordingly, the wafer port flange 2 bottoms out on the top plate 4 for proper dimensional registration between the lip 3 and the front side 11 of the wafer 10. By “bottoms out” we mean that the wafer port flange 2 rests directly on the top plate 4 and does not rest on an o-ring 19 that can be positioned between the wafer port flange 2 and the top plate 4. The o-ring 19 is configured to block the flow of atmospheric air at an interface 20 where the flange 2 rests on the top plate 4.

Also in accordance with the present invention, by providing edge shielding of the outside band 5 of the wafer 10, the lip 3 allows the wafer 10 to overhang the electrostatic chuck 6, thereby allowing edge clamping for wafer handling purposes. Consequently, the diameter of the semiconductor wafer 10 can be greater than the diameter of the electrostatic chuck 6, whereby a portion of the outside band 5 overhangs the electrostatic chuck 6. This overhang can be about 1 mm.

In processing semiconductor wafers, it is sometimes necessary to have the wafer 10 and electrostatic chuck 6 positioned in an upside down orientation, such as the embodiment illustrated in FIGS. 1 and 2. In this orientation, if the electrostatic chuck 6 should fail, the lip 3 would prevent the wafer 10 from falling into the high-vacuum chamber 1.

While the invention has been described by reference to certain typical embodiments, it should be understood that numerous changes could be made within the spirit and scope of the inventive concepts described. Accordingly, it is intended that the invention not be limited to the disclosed embodiments, but that it have the full scope permitted by the language of the following claims.

We claim:

1. An apparatus for processing a semiconductor wafer comprising:
a wafer port flange, wherein said wafer port flange includes an electrostatic chuck, and wherein said electrostatic chuck defines a circumferential gas distribution groove and a gas gap positioned between a backside of a semiconductor wafer and said electrostatic chuck; and
a top plate, wherein said top plate includes a lip, and wherein said lip is positioned to shield an outside band of said wafer.

2. The apparatus of claim 1 wherein said apparatus is positioned within a high-vacuum chamber.

3. The apparatus of claim 2 wherein said high-vacuum chamber includes an internal pressure, and wherein said internal pressure is less than 1 Torr.

4. The apparatus of claim 1 wherein said apparatus further comprises an energy source, and wherein said energy source is configured to focus a high-energy beam onto a front side of said semiconductor wafer.

5. The apparatus of claim 4 wherein said high-energy beam is selected from an ion beam, an electron beam, a gas plasma, and combinations thereof.

6. The apparatus of claim 4 wherein said energy source is a SIMOX ion shower.

7. The apparatus of claim 4 wherein said high-energy beam is focused onto said front side of said wafer in a uniform manner.

8. The apparatus of claim 1 wherein said circumferential gas distribution groove is positioned about 1 mm from an outer peripheral edge of said electrostatic chuck.

9. The apparatus of claim 1 wherein said circumferential gas distribution groove is greater than or about 0.1 mm wide and less than or about 0.2 mm deep.

10. The apparatus of claim 1 wherein said gas gap is less than or about 1 μm thick.

11. The apparatus of claim 1 further comprising a source of cooling gas, wherein said source of cooling gas is in fluid communication with said gas gap.

12. The apparatus of claim 11 wherein said source of cooling gas has a gas pressure of greater than or about 1 Torr.

13. The apparatus of claim 11 wherein said source of cooling gas has a high thermal conductivity.

14. The apparatus of claim 11 wherein said source of cooling gas is selected from nitrogen, neon, helium, or hydrogen.

15. The apparatus of claim 1 wherein
said gas gap further defines a uniform heat conduction area bounded by said circumferential gas distribution groove,
said uniform heat conduction area includes a source of cooling gas in fluid communication with said uniform heat conduction area, and
said source of cooling gas has a gas pressure that is constant across said uniform heat conduction area.

16. The apparatus of claim 15 wherein said source of cooling gas has a gas pressure of greater than or about 1 Torr.

17. The apparatus of claim 15 wherein said source of cooling gas has a high thermal conductivity.

18. The apparatus of claim 15 wherein said source of cooling gas is selected from nitrogen, neon, helium, or hydrogen.

19. The apparatus of claim 1 wherein said outside band is less than or about 3 mm.

20. The apparatus of claim 1 wherein said top plate is fluid cooled.

21. The apparatus of claim 20 wherein said fluid for cooling said top plate is water.

22. The apparatus of claim 1 wherein said top plate further comprises a silicon coating.

23. The apparatus of claim 22 wherein said silicon coating is doped with an electrically conductive material.

24. The apparatus of claim 23 wherein said electrically conductive material comprises boron.

25. The apparatus of claim 1 wherein said top plate and said electrostatic chuck are separated by a gap greater than or about 1 mm.

26. The apparatus of claim 1 wherein said lip is positioned less than or about 0.1 mm from said front side of said wafer.

27. The apparatus of claim 1 further comprising a pumping channel defined between said wafer port flange and said top plate.

28. The apparatus of claim 1 wherein said wafer port flange is arranged to rest on said top plate for proper dimensional registration between said lip and said wafer.

29. The apparatus of claim 28 further comprising an o-ring positioned between said wafer port flange and said top plate, wherein said o-ring is configured to block the flow of atmospheric air at an interface where said wafer port flange rests on said top plate.

30. The apparatus of claim 1 wherein the diameter of said wafer is greater than the diameter of said electrostatic chuck, whereby a portion of said outside band of said wafer overhangs said electrostatic chuck.

31. The apparatus of claim 30 wherein said outside band of said wafer overhangs said electrostatic chuck by about 1 mm.

32. The apparatus of claim 1 wherein said lip is positioned to catch said wafer should said electrostatic chuck fail during processing in an upside down orientation.
